(19) United States
(12) Patent Application Publication
(10) Pub. No.: US 2026/0075728 A1
(43) Pub. Date: Mar. 12, 2026

(54) LATCHABLE HANDLE, DRAWER AND RACK

(71) Applicant: Wiwynn Corporation, New Taipei City (TW)

(72) Inventors: PING SHENG YEH, New Taipei City (TW); YI-SHEN CHEN, New Taipei City (TW); Wei Chen Lin, New Taipei City (TW)

(21) Appl. No.: 18/937,205

(22) Filed: Nov. 5, 2024

(30) Foreign Application Priority Data
Sep. 9, 2024 (TW) 113134059

(51) Int. Cl. H05K 5/02; H05K 7/14

(52) U.S. Cl. CPC H05K 5/0221; H05K 7/1489; H05K 7/1492

(57) ABSTRACT

A latchable handle includes a handle, a linkage mechanism, a push mechanism and a guide component. The handle is pivotably connected to a side plate via a first pivot and configured to receive a first force along a first direction. The linkage mechanism is connected to the handle and the side plate and configured to convert the first force into a second force along an opposite direction. The push mechanism is connected to the side plate and configured to slide along the opposite direction when the handle receives the second force. The guide component is fixed to the side plate and configured to guide the push mechanism to move along a second direction perpendicular to the first direction when the push mechanism slides along the opposite direction, such that the push mechanism pushes a first pillar disposed on a casing to transmit the second force to the handle.

### CROSS-REFERENCE TO RELATED APPLICATIONS

This non-provisional application claims priority under 35 U.S.C. § 119(a) on Patent Application No(s). 113134059 filed in Taiwan, R.O.C. on Sep. 9, 2024, the entire contents of which are hereby incorporated by reference.

### TECHNICAL FIELD

The disclosure relates to a latchable handle, a drawer and a rack, more particularly to a latchable handle, a drawer and a rack which facilitates to push and pull.

### BACKGROUND

In general, a server rack can accommodate a plurality of sleds, each sled is configured to carry a computing circuit of a server. There are two types of power supply hardware designs for server: one is to integrate a computing circuit and a power circuit into a same motherboard and carry them in a sled; the other is to integrate multiple power circuits into one power module. Both designs require plug(s) of the power circuit to be inserted into the power busbar in the server rack to obtain power. However, the more plugs the power circuits or module contains, the greater the overall mating force that needs to be overcome, making it quite laborious to install/remove the power circuits or module on/from the power busbar.

In addition, the power busbar and the plugs are installed on the rear side of the server rack. When there is no aisle on the rear side, an operator has to bend his or her upper body deep into the server rack to apply force easily, making it quite inconvenient to install/remove the power circuits or module on/from the power busbar. Therefore, how to address the aforementioned issues are one of the topics in this field.

### SUMMARY

The disclosure provides a latchable handle, a drawer and a rack which enables the operator to install/remove the power module on/from the power busbar in the rack in a simple and effortless manner.

One aspect of the disclosure provides a latchable handle. The latchable handle is assembled between a casing of a rack and a side plate of a drawer. The latchable handle includes a handle, a linkage mechanism, a push mechanism and a guide component. The handle is pivotably connected to the side plate via a first pivot, and configured to receive a first force along a first direction. The linkage mechanism is connected to the handle and the side plate, and configured to convert the first force into a second force along an opposite direction. The push mechanism is connected to the side plate, and configured to slide along the opposite direction when the handle receives the second force. The guide component is fixed to the side plate, and configured to guide the push mechanism moving along a second direction perpendicular to the first direction when the push mechanism slides along the opposite direction, such that the push mechanism pushes a first pillar disposed on the casing to transmit the second force to the handle.

Another aspect of the disclosure provides a drawer. The drawer is configured to be slidably mounted in a rack. The drawer includes a box, two aforementioned latchable handles and a connection link. The box includes a plurality of casings and a rear cover, and configured to accommodate at least one electronic device. Two ends of the connection link are respectively connected to the two latchable handles.

Still another aspect of the disclosure provides a rack. The rack includes a rack and a drawer. The rack includes a first pillar and a power busbar. The drawer is slidably mounted in the rack, and includes an electronic device and the aforementioned latchable handle. The electronic device has at least one plug. The latchable handle is configured to receive a first force and convert the first force into a second force. When the drawer is pushed toward a rear side of the rack, the first pillar gradually approaches the latchable handle; when the first pillar abuts the latchable handle, the second force is transmitted to the latchable handle, and the at least one plug is inserted into the power busbar.

As discussed above, the latchable handle, the drawer and the rack of the disclosure have the following advantages: (1) the first force applied to the handle is converted into the second force via the linkage mechanism, and the reaction force of the second force helps to overcome the mating force between the plug and the power busbar; (2) when the handle is pulled out, the holding mechanism automatically latches the handle in the first angle for preventing the handle from freely falling down to ensure the safety of the operator; (3) when packing up the handle is required, the release mechanism can automatically release the latch for ease of operation; (4) the push mechanism and elastic force stored in other elastic components can drive corresponding components back to their original positions, which prevents interference between components and increases the ease of operation. As a result, the disclosure enables the operator to install the plug on the power busbar in a simple and effortless manner.

### BRIEF DESCRIPTION OF THE DRAWINGS

The present disclosure will become better understood from the detailed description given herein below and the accompanying drawings which are given by way of illustration only, and wherein:

FIG. 1 is a partial enlarged perspective view of a rack according to one embodiment of the disclosure;

FIG. 2 is a partial enlarged perspective view of a rack and rails in FIG. 1;

FIG. 3 is a perspective view of a drawer in FIG. 1;

FIG. 4 is a partial front view of a side plate and a latchable handle according to a first embodiment of the disclosure;

FIG. 5 is a partial side view of the side plate and the latchable handle in FIG. 4;

FIG. 6 is a perspective and partial enlarged view of the latchable handle in FIG. 4;

FIGS. 7 to 12 show the operation of the latchable handle in FIG. 4 when the drawer is installing into the rack;

FIG. 13 is a partial front view of a drawer according to a second embodiment of the disclosure;

FIG. 14 is a partial exploded view of a drawer according to a third embodiment of the disclosure;

FIG. 15 is a partial side view of a side plate and a latchable handle in FIG. 14;

FIGS. 16 to 22 show the operation of the latchable handle in FIG. 14 when the drawer is installing into a rack;

FIG. 23 is a partial front view of a drawer according to a fourth embodiment of the disclosure;

FIGS. 24 and 25 show the operation of a latchable handle in FIG. 23 when the drawer is installing into a rack; and

FIG. 26 is a partial front view showing a handle in FIG. 25 is pulled out.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

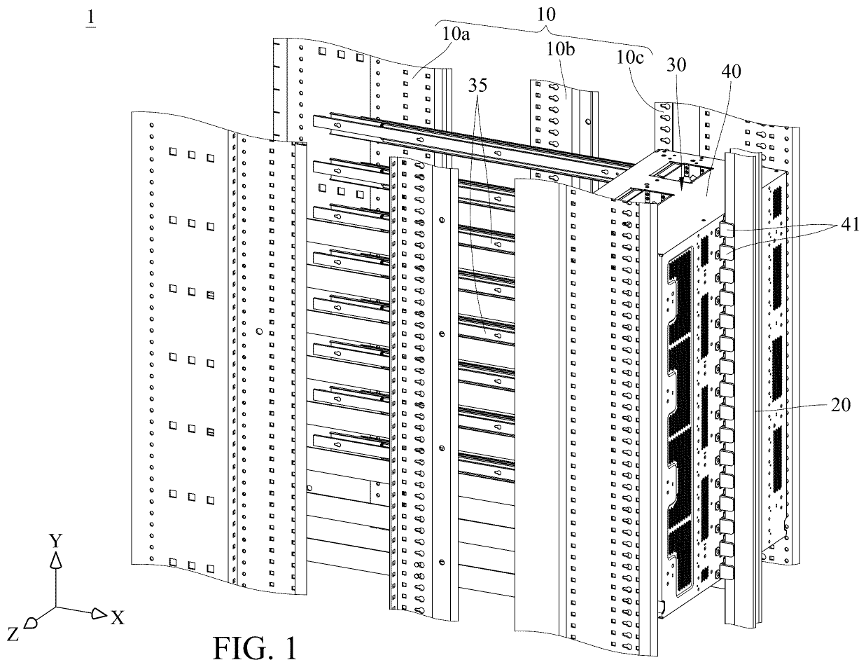

Referring to FIG. 1, which is a partial enlarged perspective view of a rack 1 according to one embodiment of the disclosure. The rack 1 is configured to accommodate at least one electronic device 40, and includes a rack 10, a power busbar 20 and a drawer 30. The rack 10 includes a plurality of casings 10a, 10b and 10c and a plurality of rails 35. The casings 10a, 10b and 10c extend along a third direction Y, the rails 35 extend along a first direction X, and each of the rails 35 is fixed to the casings 10a, 10b and 10c. The drawer 30 is slidably mounted into the rack 10 via the rails 35 along the first direction X. The drawer 30 is configured to accommodate various electronic devices 40, such as a rear power module (i.e., RPM), at least one server and so on, where the server can be carried by a sled. The electronic device 40 has at least one plug 41 disposed at a rear side of the electronic device 40 and configured to be inserted into the power busbar 20 to obtain electricity. The power busbar 20 is disposed at the rear side of the rack 10 (e.g., located between two casings) 10c, and configured to provide electricity to the electronic device 40.

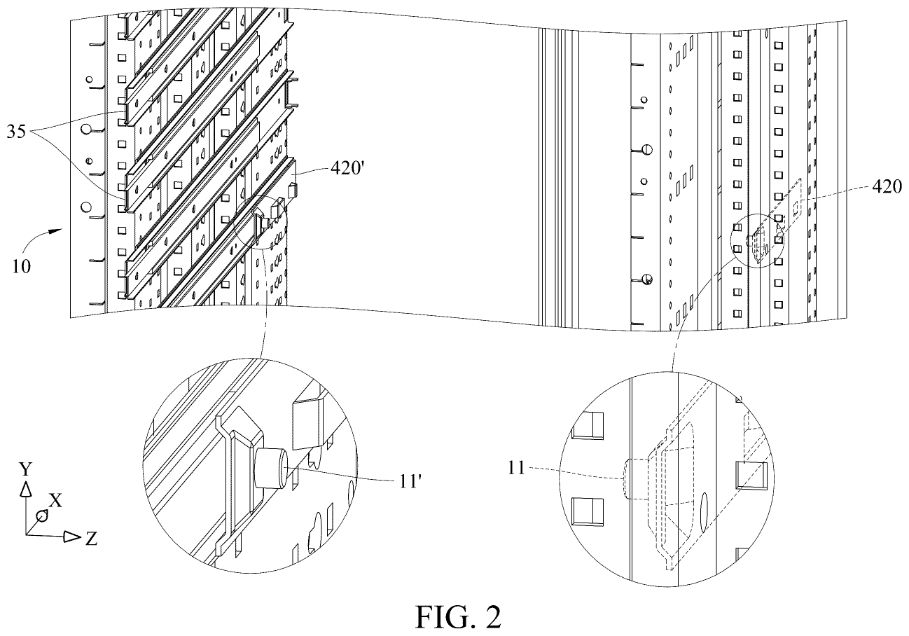

Referring to FIG. 2, which is a partial enlarged perspective view of the rack 10 and the rails 35 in FIG. 1. The rack 10 further includes two stoppers 420 and 420′ respectively fixed on two of the rails 35 located opposite to each other and configured to stop the drawer 30. The stopper 420 and 420′ respectively includes two first pillars 11 and 11′ configured to serve as a fulcrum or a force application point of a handle (now shown in FIG. 2) of the drawer 30. In one embodiment, the stoppers 420 and 420′ are respectively fixed to two of the rails 35 located lowermost. Taking the embodiment of FIG. 1 for instance, there are eight rails 35 at each of the right side and the left side of the rack 10, and the two stoppers 420 and 420′ are respectively fixed on the eighth rails 35 counting from the top to the bottom thereof. However, in another embodiment, the stoppers 420 and 420′ may be respectively fixed on two of the rails 35 located uppermost (i.e., the first rails 35).

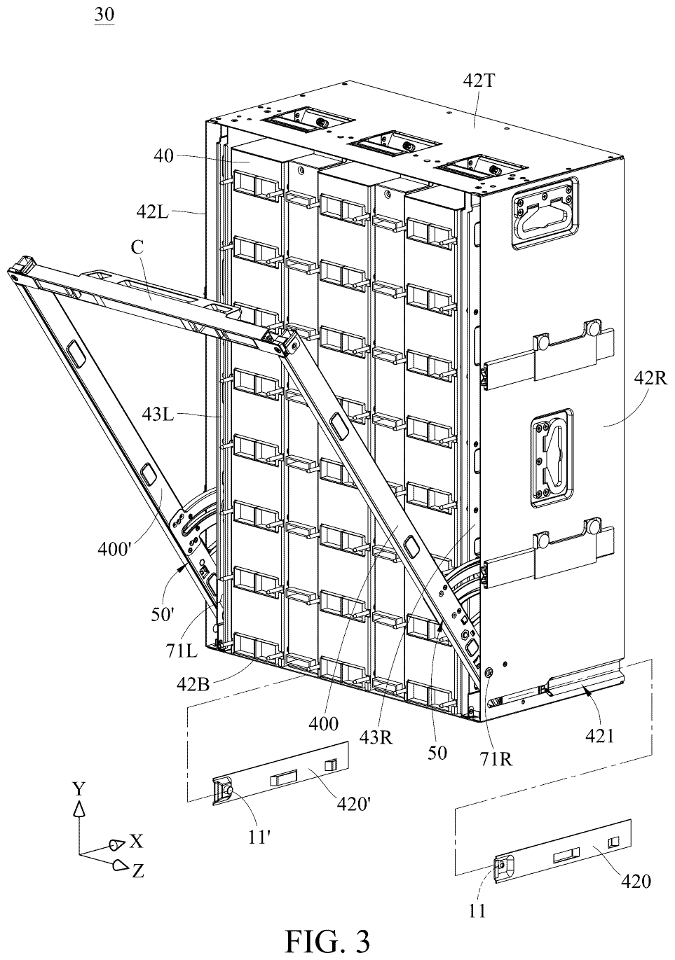

Referring to FIG. 3, which is a perspective view of the drawer 30 in FIG. 1. The drawer 30 includes a connection link C, two handles 400 and 400′, a plurality of casings 42T, 42L, 42R and 42B and a rear cover (not shown in FIG. 3). The casings 42T, 42L, 42R and 42B and the rear cover may constitute a box for accommodating the electronic device 40. One end of the handle 400 is pivotably connected to the casing 42R via a first pivot 71R, and another end of the handle 400 is connected to one end of the connection link C. One end of the handle 400′ is pivotably connected to the casing 42L via a first pivot 71L, and another end of the handle 400′ is connected to another end of the connection link C.

The drawer 30 includes two latches 50 and 50′ and two side plates 43R and 43L. The latches 50 and 50′ are structurally identical and symmetrical to each other, where the latch 50 is disposed between the side plate 43R and the casing 42R, and the latch 50′ is disposed between the side plate 43L and the casing 42L. Each of the casings 42R and 42L is formed with a guide slot 421. When the drawer 30 is pushed toward the rear side of the rack 10 along the first direction X, the first pillars 11 and 11′ of the stoppers 420 and 420′ enter the guide slot 421 to gradually approach the handles 400 and 400′. When the first pillars 11 and 11′ abut the handle 400 and 400′, the first pillars 11 and 11′ can be served as fulcrums or forces application points of the handles 400 and 400'. In this embodiment, the latch 50 and the handle 400 (or the latch 50′ and the handle 400′) can be combined into a latchable handle.

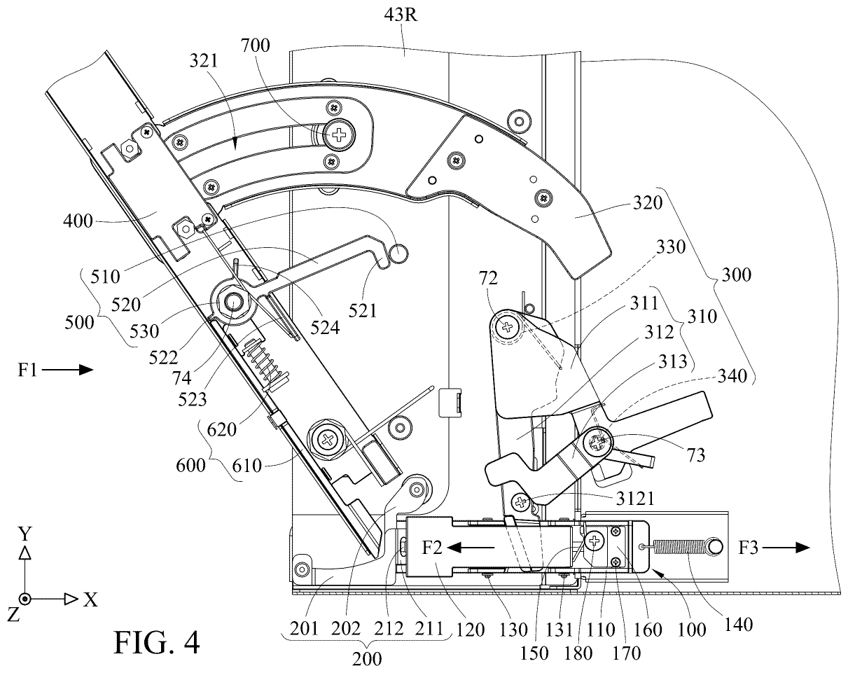

Referring to FIG. 4, which is a partial front view of the side plate 43R, the latch 50 and the handle 400 according to a first embodiment of the disclosure. The latch 50 is mounted between the casing 42R (not shown in FIG. 4) and the side plate 43R. The latch 50 includes a push mechanism 100, a guide component 200 and a linkage mechanism 300. The handle 400 is pivotably connected to the side plate 43R via the first pivot 71R, and is configured to receive a first force F1 along the first direction X. The linkage mechanism 300 is connected to the handle 400 and the side plate 43R, and is configured to convert the first force F1 into a second force F2 along an opposite direction. The push mechanism 100 is connected to the side plate 43R, and is configured to slide along the opposite direction when the handle 400 receives the second force F2. The guide component 200 is fixed to the side plate 43R, and is configured to guide the push mechanism 100 moving along a second direction Z perpendicular to the first direction X when the push mechanism 100 slides along the opposite direction, such that the push mechanism 100 pushes the first pillar 11 disposed on the stopper 420 to transmit the second force F2 to the handle 400.

The linkage mechanism 300 includes a first link 310 pivotably connected to the side plate 43R via a second pivot 72 and a second link 320 fixed to the handle 400. The first link 310 includes a pushed portion 311, a pushing portion 312, a third link 313, a first elastic component 330 and a second elastic component 340. The pushed portion 311 is pivotably connected to the side plate 43R via the second pivot 72. The pushing portion 312 is fixed to the pushed portion 311, and is pivotably connected to the side plate 43R via the second pivot 72. When the handle 400 receives the first force F1, the second link 320 drives the pushed portion 311 and the pushing portion 312 to move together. Since the pushed portion 311 is fixed to the pushing portion 312, they cannot be moved relatively. In one embodiment, the pushed portion 311 and the pushing portion 312 may be formed in one piece.

The first elastic component 330 is disposed on the side plate 43R via the second pivot 72, one end of the first elastic component 330 abuts the side plate 43R, and the first elastic component 330 is configured to keep the pushing portion 312 abutting the push mechanism 100. The third link 313 is pivotably connected to the pushed portion 311 via a third pivot 73, one end of the third link 313 abuts a second pillar 3121 of the pushing portion 312, and the third link 313 has at least one bent portion. The second elastic component 340 is disposed on the pushed portion 311 via the third pivot 73, one end of the second elastic component 340 abuts the pushed portion 311, and the second elastic component 340 is configured to keep the third link 313 abutting the second pillar 3121. In the first embodiment, the first elastic component 330 and the second elastic component 340 are torsion springs.

The push mechanism 100 includes a bracket 110 and a second pushing component 120. The bracket 110 is disposed between the side plate 43R and the casing 42R, and is slidable along the first direction X. The second pushing component 120 is slidably disposed in the bracket 110.

The push mechanism 100 further includes a fifth elastic component 140, a sixth elastic component 150, a fastening seat 160, two first fasteners 170 and a second fastener 180. Two ends of the fifth elastic component 140 are respectively fixed to the side plate 43R and the bracket 110, and the fifth elastic component 140 is configured to apply a third force F3 to the bracket 110 to move the bracket 110 along the first direction X. The fastening seat 160 are fixed to the bracket 110 via the first fasteners 170. The second fastener 180 fastens the sixth elastic component 150 on the fastening seat 160. One end of the sixth elastic component 150 abuts the fastening seat 160 on the bracket 110, and another end of the sixth elastic component 150 abuts the second pushing component 120. The sixth elastic component 150 is configured to apply a force that returns the second pushing component 120 to original position to the second pushing component 120 after the second pushing component 120 moved relative to the bracket 110. In the first embodiment, the fifth elastic component 140 is an extension spring, the sixth elastic component 150 is a torsion spring, and the first fasteners 170 and the second fastener 180 are screws. In another embodiment, the bracket 110 and the fastening seat 160 may be formed in one piece.

The guide component 200 includes a first arm 201, a second arm 202, an inclined surface 211 and a guide protrusion 212. The guide protrusion 212 is disposed on the inclined surface 211, and is configured to guide the second pushing component 120 moving along the second direction Z. The first arm 201 extends along the first direction X, and one end of the first arm 201 is fixed to the side plate 43R. The second arm 202 extends along the third direction Y, one end of the second arm 202 is connected to another end of the first arm 201, and another end of the second arm 202 is fixed to the side plate 43R.

The latch 50 further includes a holding mechanism 500. The holding mechanism 500 includes a support pillar 510, a fourth link 520 and a seventh elastic component 530. The support pillar 510 is fixed to the side plate 43R. The fourth link 520 is pivotably connected to the handle 400 via a fourth pivot 74, and has a first rod 521, a second rod 522, a third rod 523 and a fourth rod 524. When the fourth link 520 abuts the support pillar 510, an angle between the handle 400 and the third direction Y is latched to a first angle (e.g., 35 degrees). The seventh elastic component 530 is disposed on the handle 400 via the fourth pivot 74, two opposite ends of the seventh elastic component 530 respectively abuts the handle 400 and the fourth link 520, and the seventh elastic component 530 is configured to keep the fourth link 520 abutting the support pillar 510. The seventh elastic component 530 is, for example, a torsion spring. The first rod 521 of the fourth link 520 corresponds to the support pillar 510, and the first rod 521 has a bent portion for abutting the support pillar 510. The second rod 522 is located opposite to the first rod 521. The third rod 523 is disposed between the first rod 521 and the second rod 522, where one end of the seventh elastic component 530 abuts the third rod 523. The fourth rod 524 is located opposite to the third rod 523.

The latch 50 further includes a release mechanism 600. The release mechanism 600 includes a release component 610 and an eighth elastic component 620. The release component 610 is slidably disposed in the handle 400 and abuts the second rod 522 of the fourth link 520, and the release component 610 is configured to be pushed by the first pillar 11 so as to drive the fourth link 520 to detach from the support pillar 510 and drive the fourth rod 524 to abut the handle 400. Two opposite ends of the eighth elastic component 620 are respectively fixed to the handle 400 and the release component 610, and the eighth elastic component 620 is configured to keep the release component 610 abutting the second rod 522. The eighth elastic component 620 is, for example, a compression spring.

The latch 50 further includes a seventh guide pin 700. The second link 320 is formed with a seventh guide slot 321. The seventh guide pin 700 penetrates the seventh guide slot 321 along the second direction Z, and is fixed to the side plate 43R. It should be noted that without limiting the rotation angle of the handle 400, the gravitational force causes the handle 400 to fall freely to lead to potential personal injury. In order to prevent this situation, the seventh guide pin 700 and the seventh guide slot 321 are configured to limit the angle between the handle 400 and the third direction Y to 0 degrees to the first angle (e.g., 35 degrees). In this embodiment, the seventh guide pin 700 and the seventh guide slot 321 are optional structures and may be omitted.

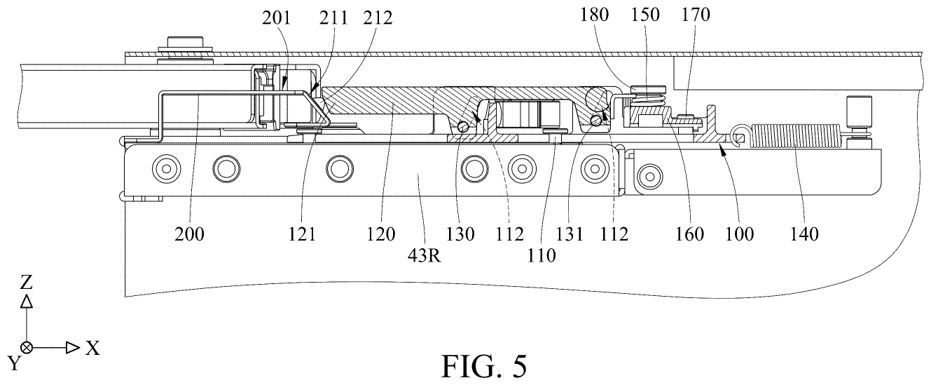

Referring to FIG. 5, which is a partial side view of the side plate 43R and the latchable handle in FIG. 4. As shown in FIG. 5, one end 121 of the second pushing component 120 abuts the guide protrusion 212. In another embodiment, the guide protrusion 212 may be omitted; in this case, the end 121 of the second pushing component 120 may abut the inclined surface 211.

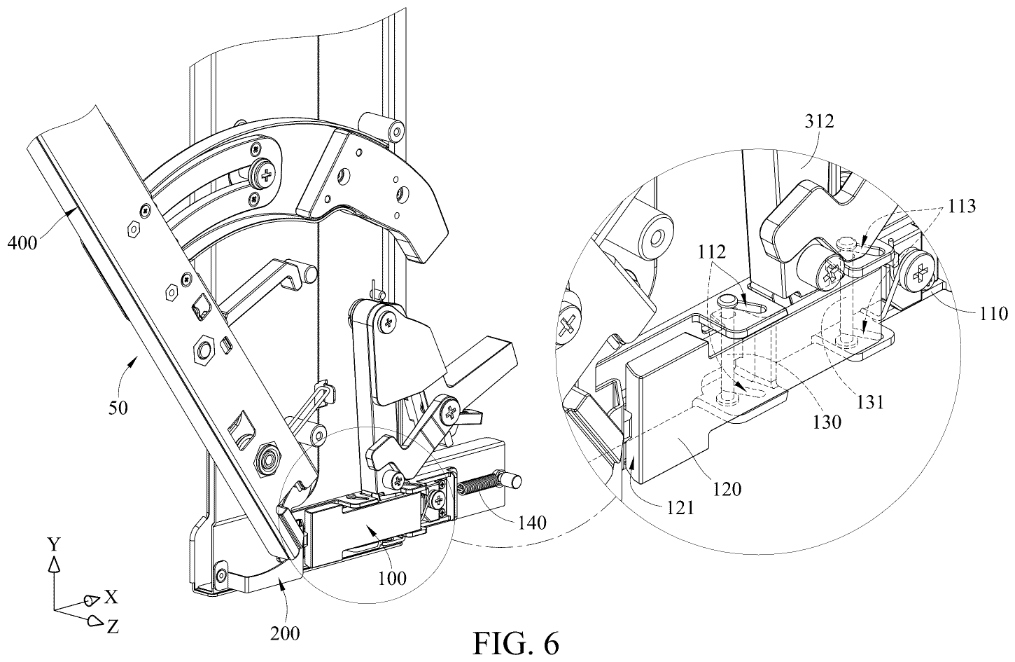

Referring to FIG. 6, which is a perspective and partial enlarged view of the latchable handle in FIG. 4. The push mechanism 100 further include a second guide pin 130 and a third guide pin 131. The bracket 110 is formed with a plurality of second guide slots 112 between the guide component 200 and the pushing portion 312 and a plurality of third guide slots 113 between the fifth elastic component 140 and the pushing portion 312. The second guide pin 130 penetrates the second pushing component 120 and the two second guide slots 112 along the third direction Y. The third guide pin 131 penetrates the second pushing component 120 and the two third guide slots 113 along the third direction Y.

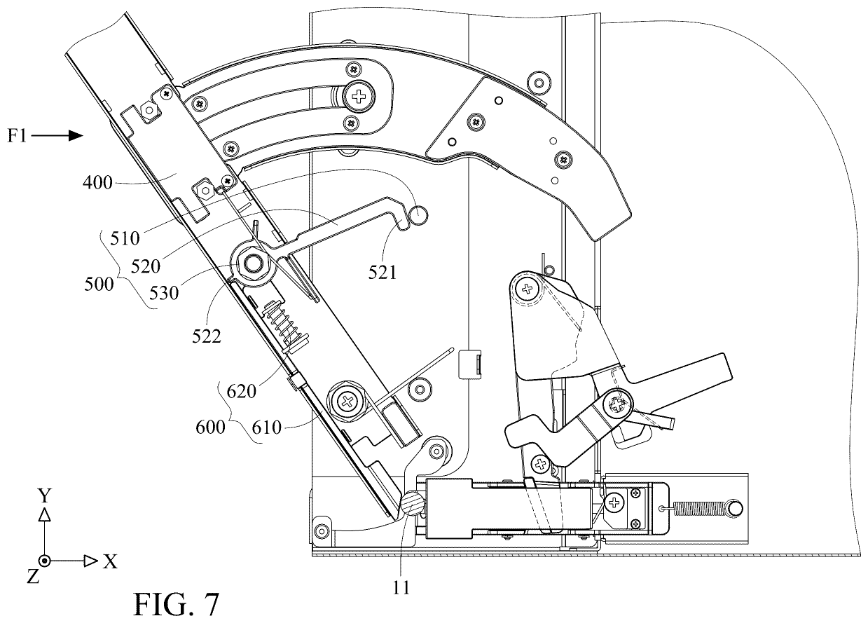

FIGS. 7 to 12 show the operation of the latchable handle in FIG. 4 when the drawer 30 is installing into the rack 10. Specifically, as shown in FIG. 7, an operator can place the drawer 30 into the rack 10 and pull out the handle 400 to the first angle (e.g., 35 degrees), such that the first rod 521 of the fourth link 520 abuts the support pillar 510 so as to keep the angle between the handle 400 and the third direction Y at the first angle. When the operator applies the first force F1 to the handle 400, the drawer 30 is pushed toward the power busbar 20 located at the rear side of the rack 10, such that the first pillar 11 of the rack 10 enters the guide slot 421 of the casing 42R and then abuts one end of the release component 610.

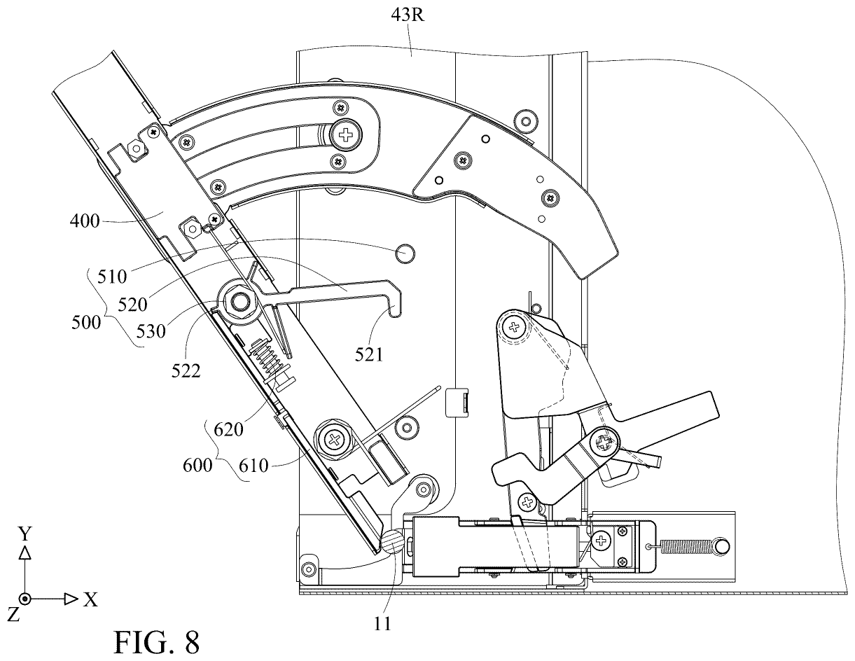

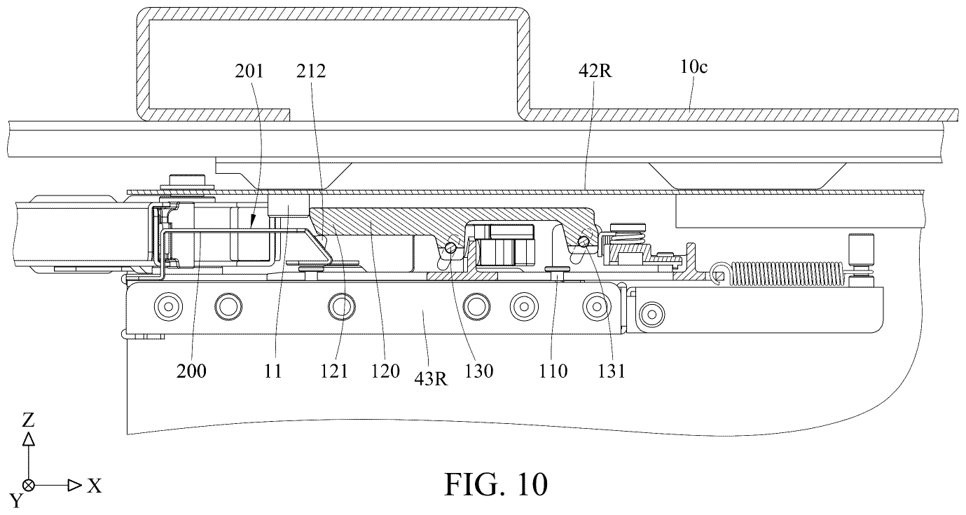

As shown in FIG. 8, when the first pillar 11 pushes the release component 610, another end of the release component 610 pushes the second rod 522 of the fourth link 520, such that the fourth link 520 rotates clockwise so as to detach the first rod 521 from the support pillar 510. As a result, the angle of the handle 400 relative to the drawer 30 is gradually reduced, such that the handle 400 is packed between the side plate 43R and the casing 42R (not shown in FIG. 8 but shown in FIG. 10).

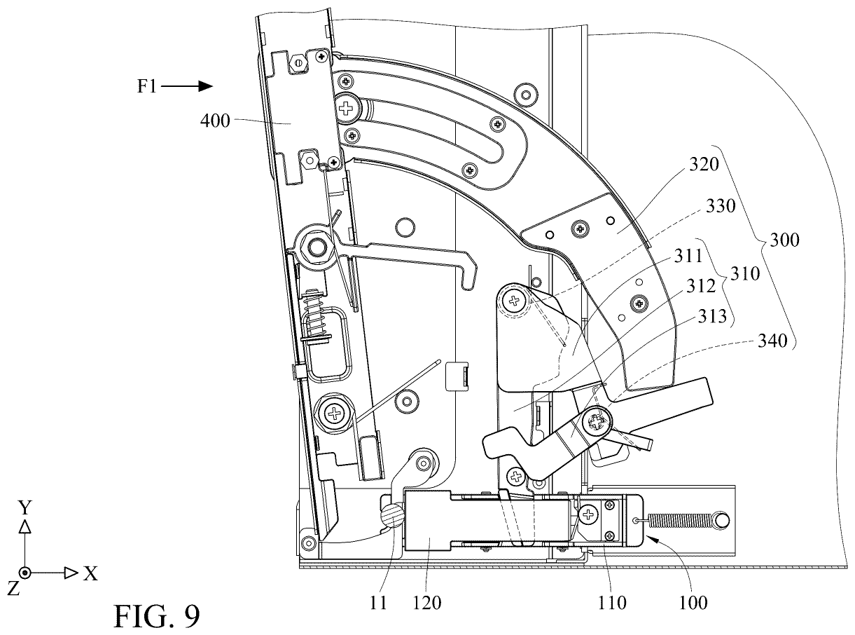

As shown in FIG. 9, during the closure of the handle 400, the first force F1 sequentially drives the second link 320, the pushed portion 311, the third link 313 and the pushing portion 312 of the first link 310, the bracket 110 and the second pushing component 120, such that the bracket 110 and the second pushing component 120 move along opposite to the first direction X. In other words, when the angle between the handle 400 and the third direction Y is decreased from the first angle (e.g., 35 degrees) to 0 degrees, the pushing portion 312 pushes the push mechanism 100 along opposite to the first direction X, where the third direction Y is perpendicular to the first direction X and the second direction Z.

As shown in FIG. 10, when the bracket 110 moves along opposite to the first direction X, the second guide pins 130, the third guide pins 131 and the second pushing component 120 sequentially move. Meanwhile, the second pushing component 120 is guided by the guide component 200 to move along the second direction Z. When the end 121 of the second pushing component 120 has crossed over the guide protrusion 212, the end 121 of the second pushing component 120 pushes the first pillar 11. In the first embodiment, the guide protrusion 212 can guide the second pushing component 120, and also can keep the end 121 of the second pushing component 120 abutting the first pillar 11.

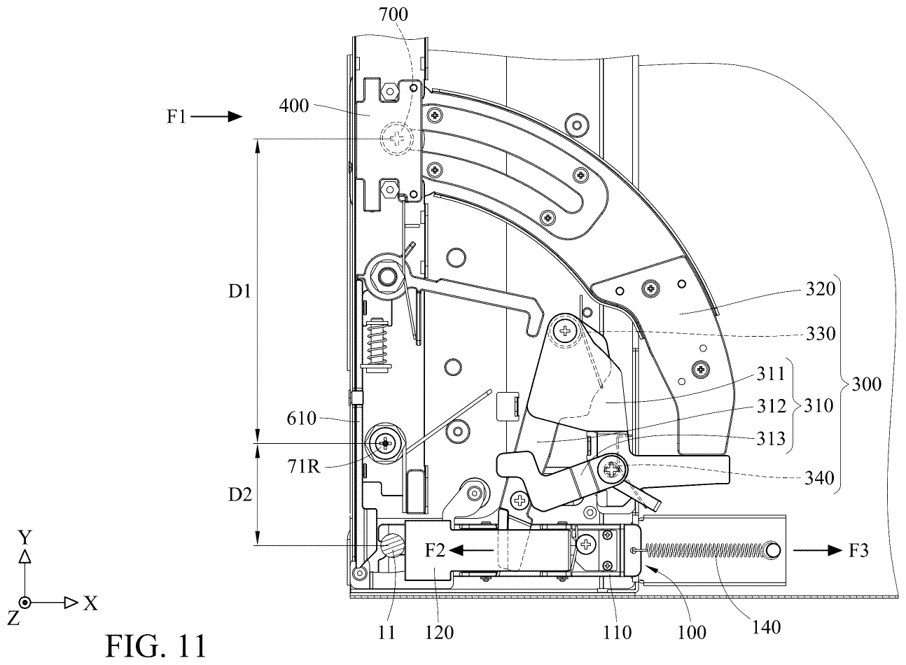

As shown in FIG. 11, when the angle between the handle 400 and the third direction Y is 0 degrees, the first force F1 is converted into the second force F2 via the linkage mechanism 300 to drive the second pushing component 120 pushing the first pillar 11. Since the first pillar 11 does not abut the handle 400 and is fixed to the rack 10, the second force F2 applied on the first pillar 11 will produce a reaction force that pushes the drawer 30 deeper into the rack 10. Therefore, when the handle 400 is packed in the drawer 30, the reaction force of the second force F2 helps to overcome the mating force between the plug 41 of the electronic device 40 and the power busbar 20.

When removal of the drawer 30 from the rack 10 is required, the operator can pull out the handle 400 counterclockwise, such that the second link 320 leaves the pushed portion 311, the third force F3 stored in the fifth elastic component 140 drives the second pushing component 120 moving along the first direction X and leaving the first pillar 11. Note that when the angle between the handle 400 and the third direction Y is 0 degrees, taking the first pivot 71R as a fulcrum, a distance D1 between the first pivot 71R and the seventh guide pin 700 (or a place where the handle is connected to the second link 320) is greater than a distance D2 between the first pivot 71R and the first pillar 11. In such a configuration, the place where the handle 400 is connected to the second link 320 moves faster, such that the second pushing component 120 leaves the first pillar 11 earlier than one end of the release component 610 abuts the first pillar 11. Therefore, the second pushing component 120 will not block the drawer 30 from moving along opposite to the first direction X.

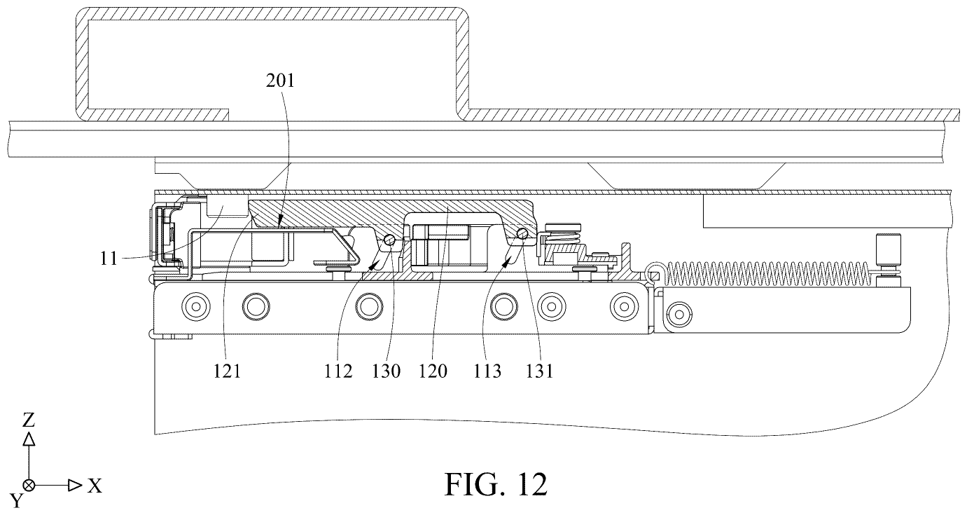

As shown in FIG. 12, when the handle 400 is packed in the drawer 30, the second guide pins 130 and the third guide pins 131 respectively moved to ends of the second guide slots 112 and ends of the third guide slots 113, and the end 121 of the second pushing component 120 abuts the first pillar 11 and is supported by the first arm 201.

In short, in the first embodiment, when the operator pulls out the handle 400 and then pushes the drawer 30 to the rear side of the rack 10, the first pillar 11 pushes the release component 610 to detach the fourth link 520 from the support pillar 510. Then, the handle 400 rotates clockwise to drive the linkage mechanism 300 pushing the push mechanism 100, such that the push mechanism 100 is guided by the guide component 200 to push the first pillar 11 of the rack 10 to drive the drawer 30 moving in the rack 10, thereby inserting the plug 41 of the electronic device 40 into the power busbar 20. Therefore, the operator can stick only hands into the rack 10 to operate the handle 400 to insert the plug 41 into the power busbar 20 in a simple and effortless manner.

On the other hand, when removal of the drawer 30 from the rack 10 is required, the operator can pull out the handle 400 from the drawer 30, such that the second link 320 leaves the pushed portion 311 of the first link 310. As a result, the force that pushes the bracket 110 is removed, such that the fifth elastic component 140 and the sixth elastic component 150 respectively drive the bracket 110 and the second pushing component 120 returning to their original positions, and the bracket 110 drives the pushed portion 311, the third link 313 and the pushing portion 312 back to their original positions. In addition, one end of the handle 400 can push the first pillar 11 of the rack 10 via the release component 610, such that the drawer 30 moves away from the power busbar 20, and the plug 41 can be detached from the power busbar 20 at once. Therefore, the operator can stick his or her hands into the rack 10 and operate the handle 400 to detach the plug 41 from the power busbar 20 in a simple and effortless manner.

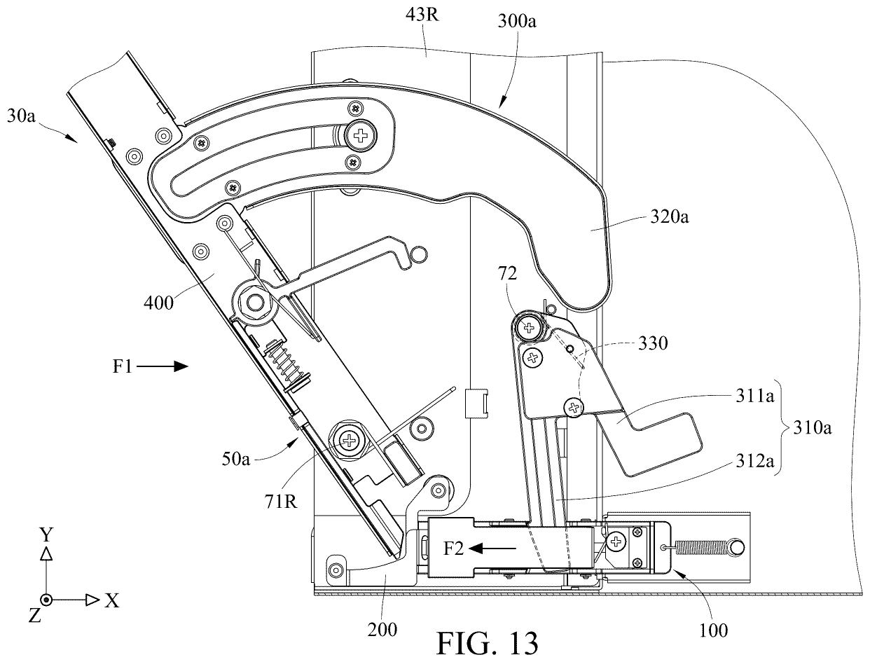

Referring to FIG. 13, which is a partial front view of a drawer 30a according to a second embodiment of the disclosure. The difference between the drawer 30a in the second embodiment and the drawer 30 in the first embodiment is mainly a structure of a linkage mechanism 300a. Same components are denoted with same symbols, and those similar parts will not be introduced again.

The linkage mechanism 300a includes a first link 310a pivotably connected to the side plate 43R via a second pivot 72 and a second link 320a fixed to the handle 400. The first link 310a includes a pushing portion 312a pivotably connected to the side plate 43R via the second pivot 72 and a pushed portion 311a fixed to the pushing portion 312a. The pushed portion 311a and the pushing portion 312a cannot be moved relatively. The first link 310a includes a first elastic component 330 disposed on the side plate 43R via the second pivot 72, two opposite ends of the first elastic component 330 respectively abuts the side plate 43R and the pushing portion 312a, and the first elastic component 330 is configured to keep the pushing portion 312a abutting the push mechanism 100. When the handle 400 receives the first force F1, the pushed portion 311a and the pushing portion 312a of the first link 310a move together via the second link 320a of the linkage mechanism 300a. When the angle between the handle 400 and the third direction Y is decreased from a first angle (e.g., 35 degrees) to 0 degrees, the pushing portion 312a pushes the push mechanism 100 along opposite to the first direction X.

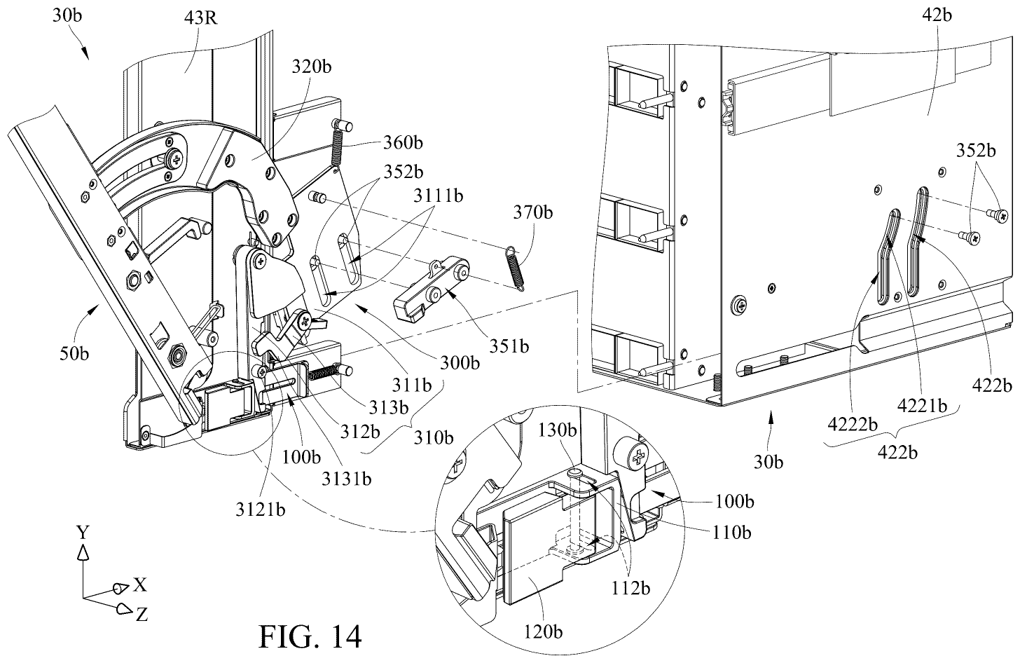

Referring to FIG. 14, which is a partial exploded view of a drawer 30b according to a third embodiment of the disclosure. The difference between the drawer 30b of the third embodiment and the drawer 30 of the first embodiment is mainly the structures of a linkage mechanism 300b and a push mechanism 100b of a latch 50b. Same components are denoted with same symbols, and those similar parts will not be introduced again.

The linkage mechanism 300b of the latch 50b includes a first link 310b and a second link 320b. The first link 310b includes a pushed portion 311b, a pushing portion 312b and a third link 313b. The pushing portion 312b and the pushed portion 311b of the first link 310b are pivotably connected to the side plate 43R together, and the third link 313b is pivotably connected to the pushed portion 311b.

The pushed portion 311b is formed with two first guide slots 3111b, and the first link 310b further includes a first pushing component 351b, a plurality of first guide pins 352b, a third elastic component 370b and a fourth elastic component 360b. The first pushing component 351b is slidably disposed in the pushed portion 311b. The first guide pins 352b penetrate the first guide slots 3111b along the second direction Z, where the first guide slots 3111b are straight guide slots. Two ends of the third elastic component 370b are fixed to the pushed portion 311b and the first pushing component 351b, and the third elastic component 370b is configured to apply a force that returns the first pushing component 351b to original position to the first pushing component 351b after the first pushing component 351b was pushed by the second link 320b. Two ends of the fourth elastic component 360b are fixed to the pushed portion 311b and the side plate 43R, and the fourth elastic component 360b is configured to apply a force that returns the pushed portion 311b to original position to the pushed portion 311b after the pushed portion 311b was pushed by the second link 320b. In the third embodiment, the third elastic component 370b and the fourth elastic component 360b are extension springs.

A casing 42b is formed with two casing slots 422b, and each of the casing slots 422b has a curve portion 4221b and a straight portion 4222b. The first pushing component 351b is located between the casing 42b and the pushed portion 311b, two of the first guide pins 352b penetrate the casing slots 422b of the casing 42b along the second direction Z and are assembled with one side of the first pushing component 351b, and other two of the first guide pins 352b penetrate the first guide slots 3111b of the pushed portion 311 along the second direction Z and are assembled with another side of the first pushing component 351b, such that the first pushing component 351b is slidably disposed in the pushed portion 311b and the casing 42b of the drawer 30b.

The push mechanism 100b includes a bracket 110b formed with two guide slot 112b located opposite to each other and a second pushing component 120b slidably disposed in the bracket 110b. The push mechanism 100b further includes a second guide pin 130b. The second guide pin 130b penetrates the bracket 110b along the third direction Y. Two opposite ends of the second guide pin 130b are slidably located in the guide slots 112b, such that the second pushing component 120b can slide relative to the bracket 110b.

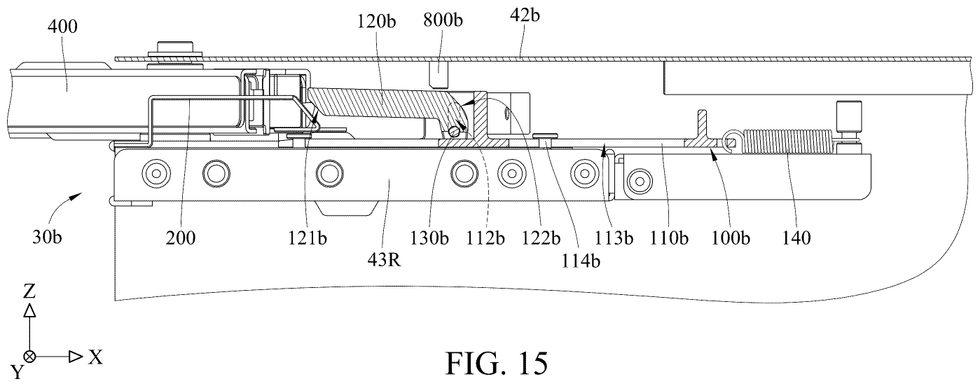

Referring to FIG. 15, which is a partial side view of the side plate 43R and a latchable handle in FIG. 14. The latch 50b further includes an abutting component 800b fixed to the casing 42b of the electronic device 40. In addition, the second pushing component 120b has a first inclined guide surface 121b and a second inclined guide surface 122b located opposite to each other. The first inclined guide surface 121b corresponds to the guide component 200, and the second inclined guide surface 122b corresponds to the abutting component 800b.

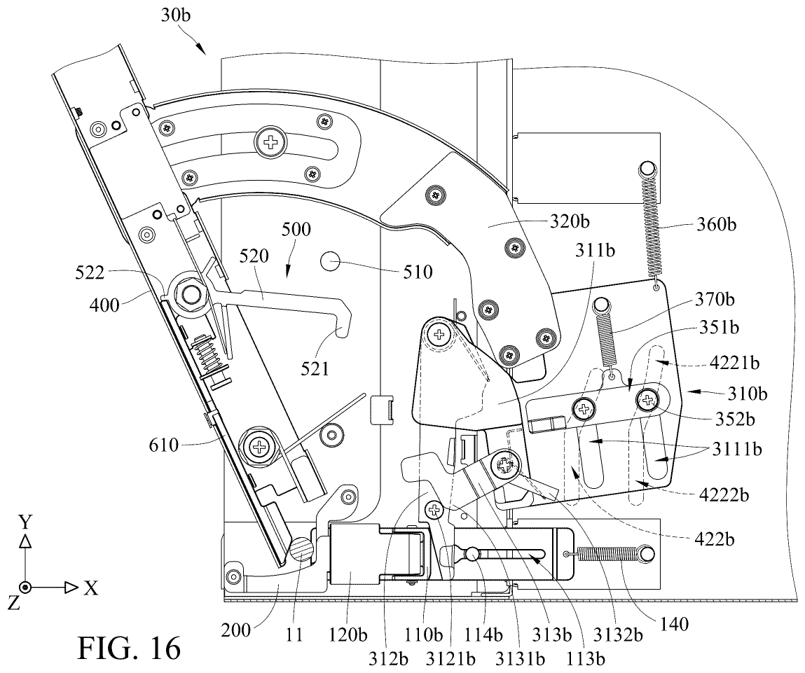

Referring to FIGS. 16 to 22, which show the operation of the latchable handle in FIG. 14 when the drawer is installing into a rack. As shown in FIG. 16, when the angle between the handle 400 and the third direction Y is decreased from a first angle (e.g., 35 degrees) to a second angle (e.g., a half of the first angle, such as 17 degrees), the handle 400 sequentially drives the second link 320b, the pushed portion 311b, the third link 313b, the pushing portion 312b and the bracket 110b, such that the bracket 110b moves along opposite to the first direction X. Meanwhile, the pushed portion 311 drives the first pushing component 351b moving along the curved portions 4221b of the casing slots 422b. The bracket 110 is formed with a fourth guide slot 113b between the second pushing component 120b and the fifth elastic component 140. In addition, the push mechanism 100 further includes a fourth guide pin 114b. The fourth guide pin 114b penetrates the fourth guide slot 113b along the second direction Z.

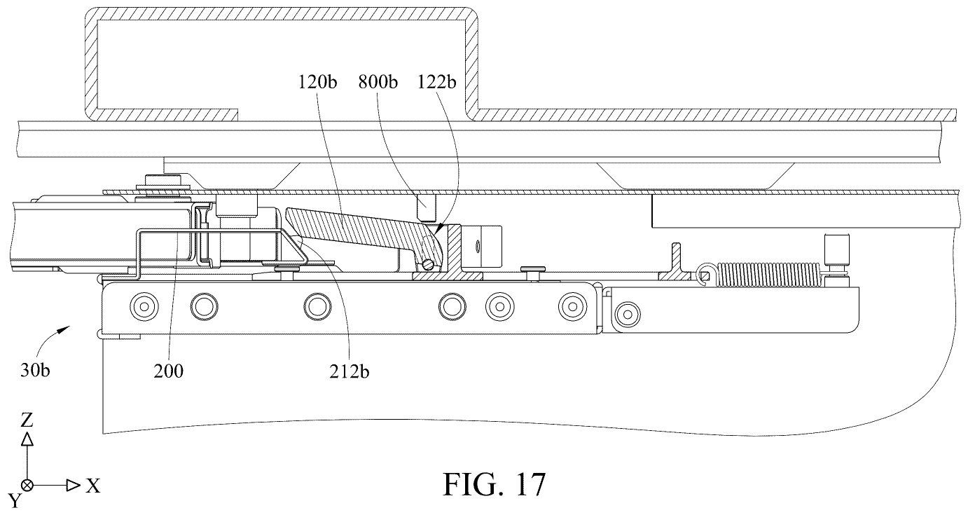

As shown in FIG. 17, the second pushing component 120b is guided by the guide protrusion 212b and the abuts component 800b to move along the second direction Z. Meanwhile, the second pushing component 120b rotates counterclockwise about the second guide pin 130b relative to the bracket 110b.

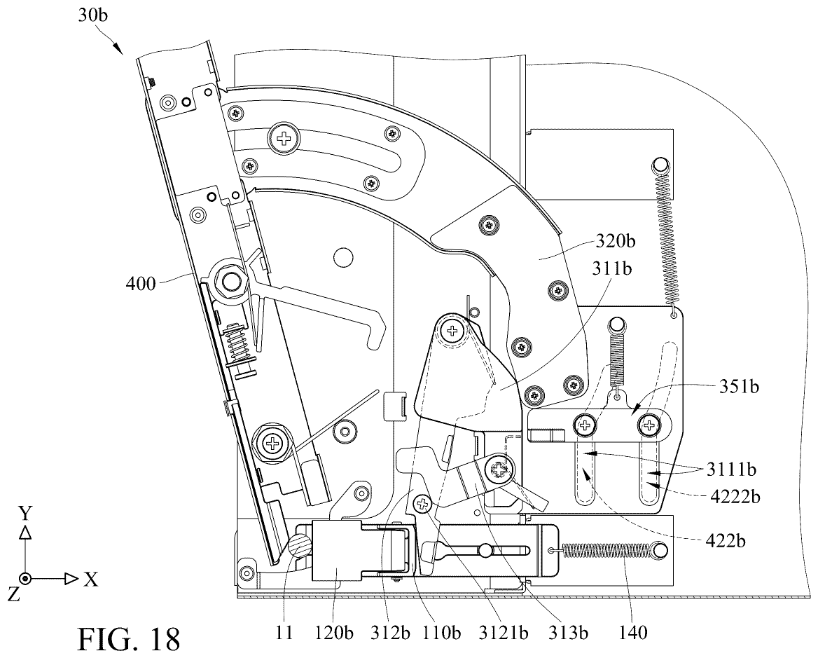

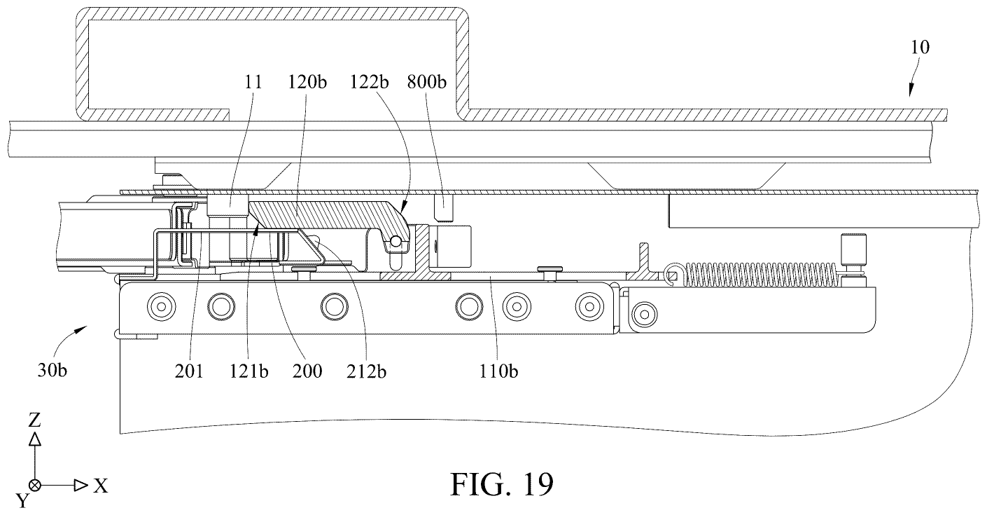

As shown in FIG. 18, when the angle between the handle 400 and the third direction Y is decreased from the second angle to 0 degrees, the second link 320b pushes the first pushing component 351b moving along the third direction Y; that is to say, the pushed portion 311 drives the first pushing component 351b moving along the straight portions 4222b of the casing slots 422b. As shown in FIG. 19, the second pushing component 120b moves to top of the guide component 200 and is supported by the first arm 201, and the second pushing component 120b pushes against the first pillar 11. Since the first pillar 11 cannot be pushed by the second pushing component 120b, a force that the second pushing component 120b pushes the first pillar 11 will produce a reaction force, and this reaction force will drive the drawer 30b moving deep into the rear side of the rack along the first direction X.

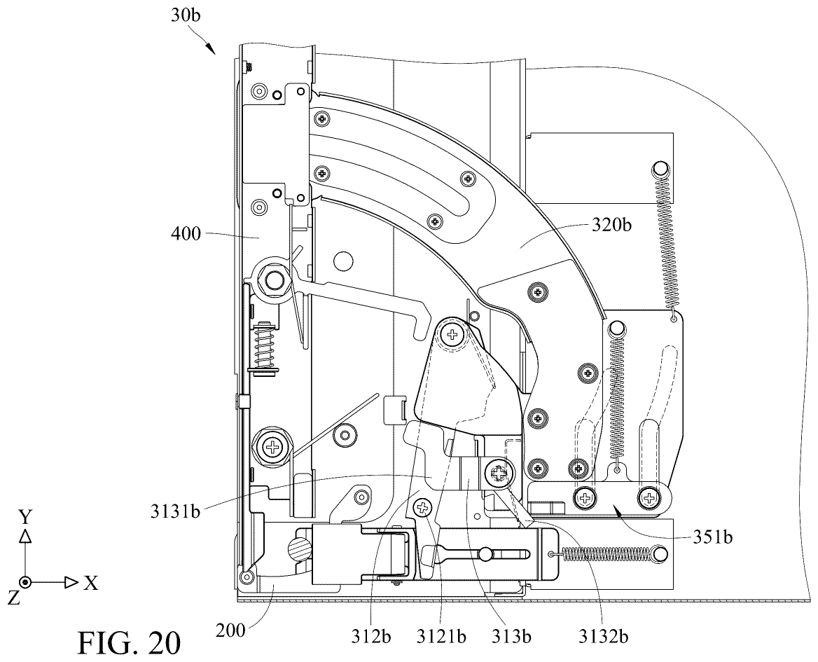

As shown in FIG. 20, when the angle between the handle 400 and the third direction Y is equal to 0 degrees, the second link 320b pushes the first pushing component 351b to push a second rod 3132b of the third link 313b, such that a first rod 3131b of the third link 313b is detached from the second pillar 3121b.

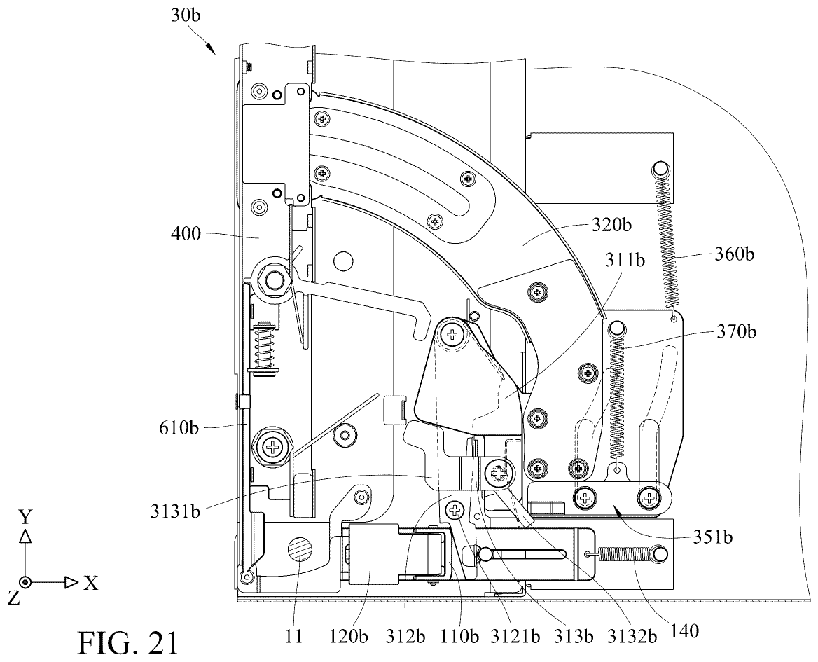

As shown in FIG. 21, after the first rod 3131b of the third link 313b is detached from the second pillar 3121b of the pushing portion 312b, the pushing portion 312b can move relative to the pushed portion 311b. As a result, the fifth elastic component 140 disposed on the bracket 110b can drive the bracket 110b returning to its original position, such that the bracket 110b drives the pushing portion 312b returning to its original position.

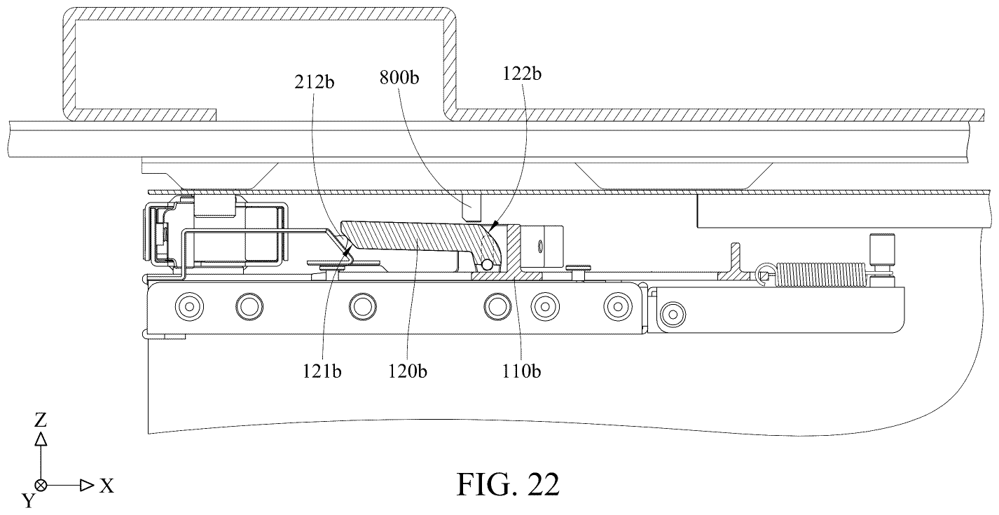

As shown in FIG. 22, during return of the bracket 110b, the second inclined guide surface 122b of the second pushing component 120b will abut the abutting component 800b, such that the second pushing component 120b slides relative to the bracket 110b and returns to its original position.

Referring to FIG. 21 again, when t removal of the drawer 30b from the rack 10 is required, the operator can pull out the handle 400 from the drawer 30b counterclockwise. The second link 320b leaves the first pushing component 351b, an elastic force stored in the third elastic component 370b drives the first pushing component 351b returning to its original position. Then, the second link 320b leaves the pushed portion 311b of the first link 310b, and an elastic force stored in the fourth elastic component 360b drives the pushed portion 311b returning to its original position. In addition, one end of the handle 400 pushes the first pillar 11 of the rack 10 via the release component 610b so as to drive the drawer 30b moving along opposite to the first direction X.

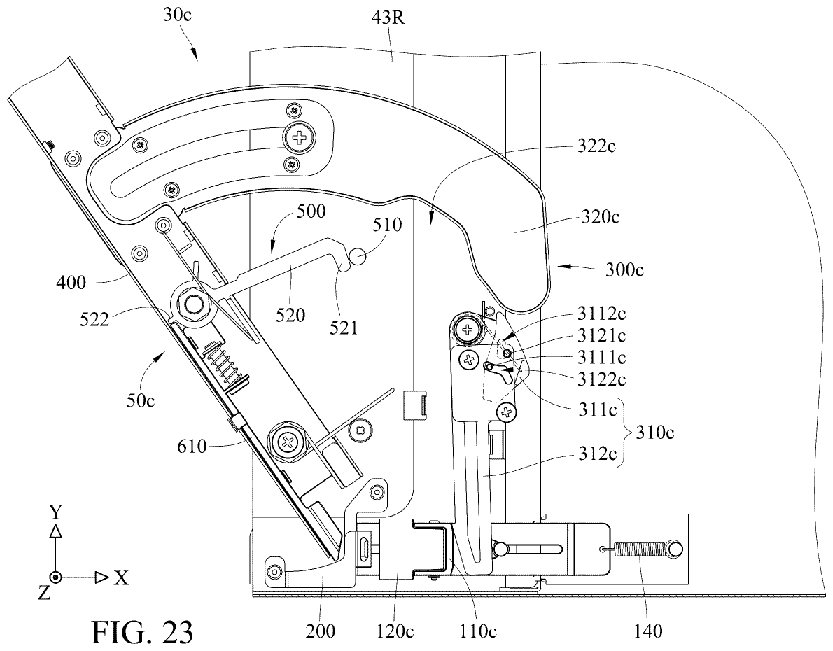

Referring to FIG. 23, which is a partial front view of a drawer according to a fourth embodiment of the disclosure. The difference between the drawer 30c of the fourth embodiment and the drawer 30b of the third embodiment is mainly a structure of a linkage mechanism 300c of a latch 50c. Same components are denoted with same symbols, and those similar parts will not be introduced again.

The linkage mechanism 300c of the latch 50c includes a first link 310c and a second link 320c. The first link 310c includes a pushed portion 311c and a pushing portion 312c. The pushed portion 311c is slidably disposed in the pushing portion 312c. The pushed portion 311c has a fifth guide pin 3111c and a fifth guide slot 3112c. The pushing portion 312c has a sixth guide pin 3121c and a sixth guide slot 3122c. The fifth guide pin 3111c of the pushed portion 311c is slidably located in the sixth guide slot 3122c of the pushing portion 312c, and the sixth guide pin 3121c of the pushing portion 312c is slidably located in the fifth guide slot 3112c of the pushed portion 311c. The pushing portion 312c is pivotably connected to the side plate 43R of the electronic device 40. On the other hand, the second link 320c is formed with a recess 322c.

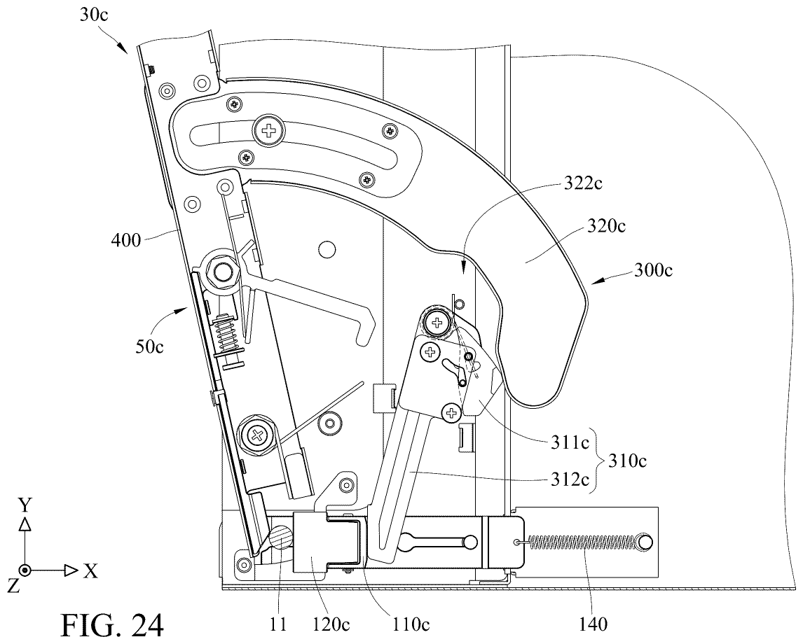

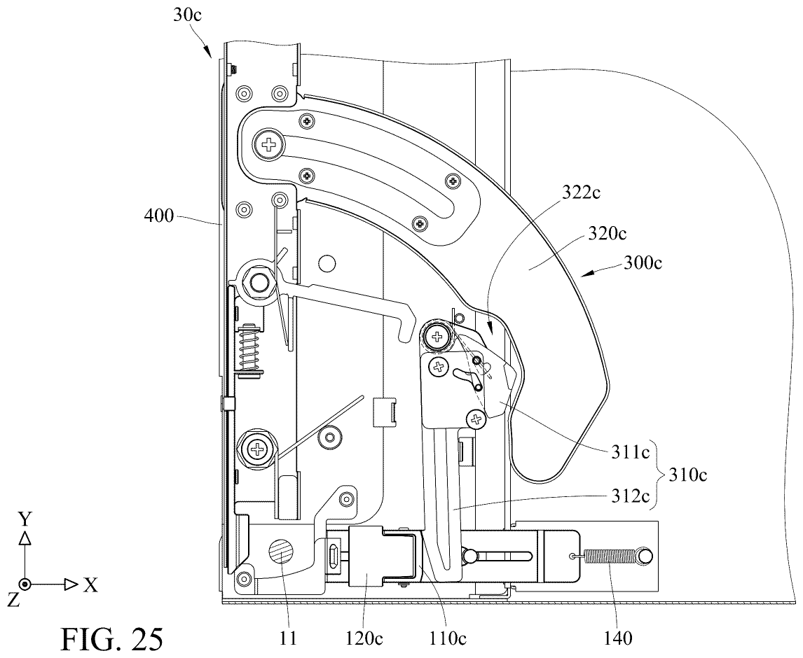

Referring to FIGS. 24 and 25, which show the operation of the latchable handle in FIG. 23 when the drawer 30c is installing into the rack. As shown in FIG. 24, when the angle between the handle 400 and the third direction Y is decreased from the first angle (e.g., 35 degrees) to the second angle (e.g., a half of the first angle, such as 17 degrees), the handle 400 sequentially drives the second link 320c, the pushed portion 311c, the pushing portion 312c, the bracket 110c and the second pushing component 120c, such that the second pushing component 120c moves along opposite to the first direction X. As a result, the second pushing component 120c is guided by the guide component 200 to abut the first pillar 11, thereby driving the drawer 30c to move deep into the rear side of the rack along the first direction X.

As shown in FIG. 25, when the angle between the handle 400 and the third direction Y is 0 degrees, the pushed portion 311c is partially packed in the recess 322c of the second link 320c and will not be driven by the second link 320. As a result, the second link 320c is detached from the pushed portion 311c, and an elastic force stored in the fifth elastic component 140 drives the bracket 110c returning to its original position, forces the second pushing component 120c detaching from the first pillar 11 of the rack and returns the pushing portion 312c to its original position.

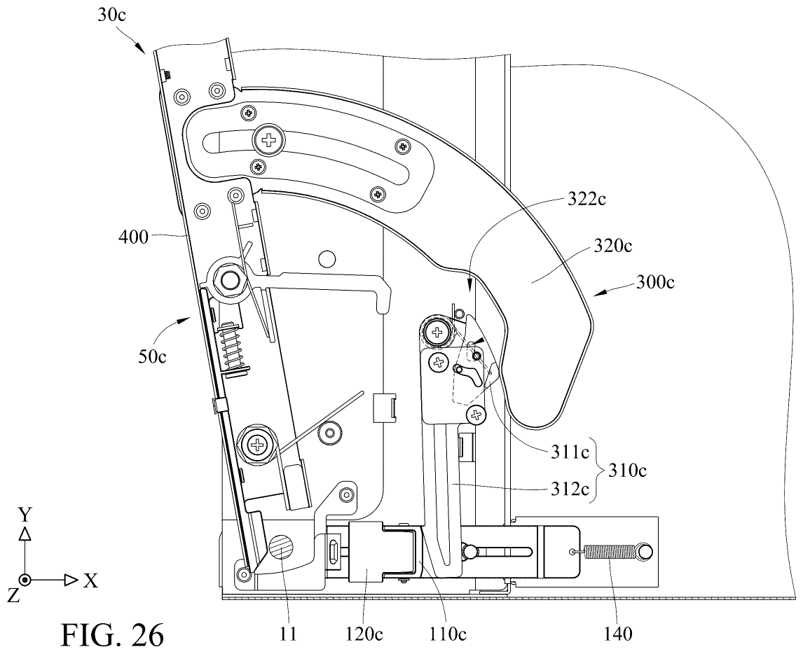

Referring to FIG. 26, which is a partial front view showing the handle 400 in FIG. 25 is pulled out. When the handle 400 is pulled out from the drawer 30c, the second link 320c pushes the pushed portion 311c returning to its original position along the third direction Y.

As discussed above, the latchable handle, the drawer and the rack of the disclosure have the following advantages: (1) the first force applied to the handle is converted into the second force via the linkage mechanism, and the reaction force of the second force helps to overcome the mating force between the plug and the power busbar; (2) when the handle is pulled out, the holding mechanism automatically latches the handle in the first angle for preventing the handle from freely falling down to ensure the safety of the operator; (3) when packing up the handle is required, the release mechanism can automatically release the latch for increasing the operation convenience; (4) the push mechanism and elastic force stored in other elastic components can drive corresponding components back to their original positions, which prevents interference between components and increases the operation convenience. As a result, the disclosure enables the operator to install the plug on the power busbar in a simple and effortless manner.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A latchable handle assembled between a casing of a rack and a side plate of a drawer, the latchable handle comprising:
a handle pivotably connected to the side plate via a first pivot, and configured to receive a first force along a first direction;
a linkage mechanism connected to the handle and the side plate, and configured to convert the first force into a second force along an opposite direction;
a push mechanism connected to the side plate, and configured to slide along the opposite direction when the handle receives the second force; and
a guide component fixed to the side plate, and configured to guide the push mechanism moving along a second direction perpendicular to the first direction when the push mechanism slides along the opposite direction, such that the push mechanism pushes a first pillar disposed on the casing to transmit the second force to the handle.

2. The latchable handle according to claim 1, wherein the linkage mechanism comprises:
a first link pivotably connected to the side plate via a second pivot; and
a second link fixed to the handle.

3. The latchable handle according to claim 2, wherein the first link comprises:
a pushed portion pivotably connected to the side plate via the second pivot; and
a pushing portion fixed to the pushed portion and pivotably connected to the side plate via the second pivot;
wherein, when the handle receives the first force, the second link drives the pushed portion and the pushing portion moving together; when an angle between the handle and a third direction is from a first angle to 0 degrees, the pushing portion pushes the push mechanism moving along the opposite direction, wherein the third direction is perpendicular to the first direction and the second direction.

4. The latchable handle according to claim 3, wherein the first link further comprises:
a first elastic component disposed on the side plate via the second pivot, having two opposite ends respectively abutting the side plate and the pushing portion, and configured to keep the pushing portion abutting the push mechanism.

5. The latchable handle according to claim 3, wherein the first link further comprises:
a first elastic component disposed on the side plate via the second pivot, having one end abutting the side plate, and configured to keep the pushing portion abutting the push mechanism;
a third link pivotably connected to the pushed portion via a third pivot, having one end abutting a second pillar of the pushing portion, and having at least one bent portion; and
a second elastic component disposed on the pushed portion via the third pivot, having one end of the second elastic component abutting the pushed portion, and configured to keep the third link abutting the second pillar.

6. The latchable handle according to claim 5, wherein the pushed portion is formed with two first guide slots, and the first link further comprises:
a first pushing component slidably disposed in the pushed portion;
two first guide pins penetrating the two first guide slots along the second direction;
a third elastic component having two ends fixed to the pushed portion and the first pushing component; and
a fourth elastic component having two ends fixed to the pushed portion and the side plate.

7. The latchable handle according to claim 6, wherein the casing is formed with two casing slots, each of the two casing slots has a curve portion and a straight portion, and the two first guide pins respectively penetrate the two casing slots.

8. The latchable handle according to claim 6, wherein, when the angle between the handle and the third direction is from the first angle to a second angle, the second link pushes the first pushing component moving along the third direction; when the angle between the handle and the third direction is equal to 0 degrees, the first pushing component pushes a second rod of the third link to detach a first rod of the third link from the second pillar.

9. The latchable handle according to claim 1, wherein the push mechanism comprises:
a bracket formed with two second guide slots between the guide component and the pushing portion;
a second pushing component slidably disposed in the bracket;
a fifth elastic component having two opposite ends respectively fixed to the side plate and the bracket, and configured to apply a third force to the bracket to move along the first direction; and
a second guide pin penetrating the second pushing component and the two second guide slots along a third direction, wherein the third direction is perpendicular to the first direction and the second direction.

10. The latchable handle according to claim 9, wherein the bracket is formed with two third guide slots between the fifth elastic component and the pushing portion, and the push mechanism further comprises:
a third guide pin penetrating the second pushing component and the two third guide slots along the third direction; and
a sixth elastic component having two ends abutting the bracket and the second pushing component, and disposed between the two third guide slots and the fifth elastic component.

11. The latchable handle according to claim 9, wherein the bracket is formed with a fourth guide slot between the second pushing component and the fifth elastic component, and the push mechanism further comprises:
a fourth guide pin penetrating the fourth guide slot along the second direction.

12. The latchable handle according to claim 3, wherein the pushed portion comprises a fifth guide pin and a fifth guide slot, the pushing portion comprises a sixth guide pin and a sixth guide slot, the fifth guide pin is slidably located in the sixth guide slot, and the sixth guide pin is slidably located in the fifth guide slot.

13. The latchable handle according to claim 1, wherein the guide component comprises:
a first arm extending along the first direction, and having one end fixed to the side plate;
a second arm extending along a third direction, having one end connected to another end of the first arm, and having another end fixed to the side plate;
an inclined surface extending along the first direction, and having one end connected to the first arm and the second arm; and
a guide protrusion disposed on the inclined surface, and configured to guide the second pushing component moving along the second direction.

14. The latchable handle according to claim 1, further comprising a holding mechanism comprising:
a support pillar fixed to the side plate;
a fourth link pivotably connected to the handle via a fourth pivot, wherein, when the fourth link abuts the support pillar, an angle between the handle and the third direction is latched to a first angle; and
a seventh elastic component disposed on the handle via the fourth pivot, having two opposite ends respectively abutting the handle and the fourth link, and configured to keep the fourth link abutting the support pillar.

15. The latchable handle according to claim 14, wherein the fourth link comprises:
a first rod having a bent portion for abutting the support pillar;
a second rod disposed opposite to the first rod;
a third rod disposed between the first rod and the second rod, wherein one end of the seventh elastic component abuts the third rod; and
a fourth rod disposed opposite to the third rod.

16. The latchable handle according to claim 15, further comprising a release mechanism comprising:
a release component slidably disposed in the handle, and configured to be pushed by the first pillar to detach the fourth link from the support pillar and force the fourth rod abutting the handle; and
an eighth elastic component having two opposite ends respectively fixed to the handle and the release component, and configured to keep the release component abutting the second rod.

17. The latchable handle according to claim 2, wherein the second link is formed with a seventh guide slot, a seventh guide pin penetrates the seventh guide slot along the second direction and is fixed on the side plate, the seventh guide pin and the seventh guide slot are configured to restrict an angle between the handle and a third direction between a first angle to 0 degrees, wherein the third direction is perpendicular to the first direction and the second direction.

18. A drawer configured to be slidably mounted in a rack, comprising:
a box comprising a plurality of casings and a rear cover, and configured to accommodate at least one electronic device;
two latchable handles according to claim 1; and
a connection link having two ends respectively connected to the two latchable handles.

19. A rack comprising:
a rack comprising a first pillar and a power busbar; and
a drawer slidably mounted in the rack and comprising:
an electronic device having at least one plug; and
the latchable handle according to claim 1 configured to receive a first force and convert the first force into a second force;
wherein when the drawer is pushed toward a rear side of the rack, the first pillar gradually approaches the latchable handle; when the first pillar abuts the latchable handle, the second force is transmitted to the latchable handle, and the at least one plug is inserted into the power busbar.

20. The rack according to claim 19, wherein the rack further comprises:
a plurality of casings extending along a third direction, wherein the third direction is perpendicular to the first direction and the second direction;
a plurality of rails extending along the first direction, wherein each of the plurality of rails is fixed to the plurality of casings, and the drawer is slidably mounted in the rack via one of the plurality of rails along the first direction; and
a stopper fixed in one of the plurality of rails, and configured to stop the drawer, wherein the first pillar is disposed on the stopper.
